(19) United States
(12) Patent Application Publication
(10) Pub. No.: US 2002/0025377 A1
(43) Pub. Date: Feb. 28, 2002

(54) Method of producing a ferroelectric solid-state layer using an auxiliary substance

(76) Inventors: Alfred Kersch, Putzbrunn (DE); Andreas Spitzer, Ottobrunn (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/939,330

(22) Filed: Aug. 24, 2001

(30) Foreign Application Priority Data
Aug. 24, 2000 (DE) 100 41 698.5

(51) Int. Cl. C23C 16/00

(52) U.S. Cl. 427/255.28

(57) ABSTRACT

In addition to the starting gases containing the elements of the solid-state layer to be deposited, at least one auxiliary substance is introduced into the reaction space of a reactor chamber. This auxiliary substance contains molecules which have a dipole moment and which have the property of briefly attaching themselves during the deposition process to the substrate surface with a dipole moment perpendicular to the substrate surface. In this way, the crystal structure of the solid-state layer to be grown on is dictated.

### BACKGROUND OF THE INVENTION

1. Field of the Invention

The invention relates to a method of producing a ferroelectric or paraelectric solid-state layer by chemical vapor deposition (CVD) on a substrate.

In semiconductor technology, in particular silicon technology, it is known to use ferroelectric or paraelectric materials for various purposes. Layers of this type can be used as a substitute for the normal dielectric, which includes an oxide or nitride layer, of a storage capacitor of a DRAM semiconductor memory. The advantage of these FeRAMs (Ferroelectric Random Access Memories), as they are known, is that the ferroelectric material has a very much higher dielectric constant and that a non-volatile memory chip can be produced by means of the remanent polarization of the ferroelectric material.

Furthermore, in the case of MOS transistors, a ferroelectric layer may be formed, as a substitute for the gate oxide layer, as an insulating layer between the gate electrode and the channel portion of the semiconductor surface, allowing a nonvolatile memory transistor to be produced.

Examples of conceivable ferroelectric materials for a practical application in a ferroelectric storage capacitor or a memory transistor are the compositions known as strontium-bismuth-tantalate, SrBi₂Ta₂O₉ (SBT) and SrBi₂(Ta, Nb)₂O₉ (SBTN), and furthermore Pb(Zr, Ti)O₃ (PZT, lead-zirconatetitanate) or Bi₄Ti₃O₁₂ (BTO). An example of a known paraelectric material is barium-strontium-titanate in the composition (Ba, Sr)TiO₃ (BST).

For the imagined applications as a ferroelectric memory device with extreme packing density, it is necessary to deposit the ferroelectric or paraelectric materials with a sufficiently high rate of deposition and with very good uniformity of the layer thickness and stoichiometry over a large wafer. These requirements can be satisfied in principle by deposition from the vapor phase, i.e. a CVD (Chemical Vapor Deposition) process, in particular—if metals are involved—a metal-organic CVD (MOCVD) process. In the recent past, precursors for the materials have been identified and evaluated. In the case of paraelectric BST, these are, for example, Ti(ipro)₂ (thd)₂ (ipro=isopropoxy), thd=2,2,6,6-tetramethylheptane-3,5-diketone, Ba (thd)₂ and Sr (thd)₂, which are precipitated in an oxidizing atmosphere and in a thermally activated state. In the case of ferroelectric SBT, these are, for example, Sr (thd)₂, Bi (thd)₃ and Ta (ipro)₄ (thd), which are precipitated in an oxidizing atmosphere and in a thermally activated state. To obtain the desired paraelectric or ferroelectric material properties, it is necessary to deposit the film in the correct stoichiometry and in a suitable arrangement at the atomic level, in order that, for example in the case of SBT, the Aurivillius phase forms with suitable stoichiometry, grain size and a preferred [100] and [110] orientation.

For the CVD process, the metal-organic compounds are made gaseous in an evaporator and passed together with the carrier gas argon and oxygen over a distributor plate (perforated plate) into the reactor chamber. The precursors reach the wafer, which has been heated up to a higher temperature in order to supply the necessary activation energy for the deposition. The reaction products and the undecomposed radicals are then transported by the gas flow into the outer region of the reactor, from where they are pumped away. At this point in time, further reactions take place in the vapor phase and on the inside walls of the reactor.

In the process evaluation, problems were observed both in the deposition of BST and in the deposition of SBT. In the case of BST, the uniformity on the wafer was not adequate. Both a decreasing layer thickness from the center to the edge and a changing stoichiometry were found. In addition, the relative frequency of the crystal orientations altered. In the case of SBT, there was initial success in producing ferroelectric layers in a reactor. If, however, the process was carried out in a reactor with a different geometry (the main difference here was the much smaller distance between the distributor plate and the substrate wafer), the polarizability of the layer was much less.

### SUMMARY OF THE INVENTION

It is accordingly an object of the invention to provide a method of producing a ferroelectric or paraelectric solid-state layer by chemical vapor deposition which overcomes the above-mentioned disadvantageous of the prior art methods of this general type. In particular, it is an object of the invention to provide a method of producing a ferroelectric or paraelectric solid-state layer by chemical vapor deposition with which layers of adequate uniformity with regard to the layer thickness, the stoichiometry and the electrical properties can be produced.

With the foregoing and other objects in view there is provided, in accordance with the invention, a method of producing a crystalline solid-state layer by chemical vapor deposition, that includes steps of: providing a substrate having a surface in a reaction space; and performing chemical vapor deposition by introducing, into the reaction space, starting gases containing elements of a solid-state layer to be deposited on the surface of the substrate and introducing, into the reaction space, at least one auxiliary substance. The auxiliary substance is provided in a form containing molecules which have a dipole moment and which have a property of briefly attaching themselves, during a deposition process, to the surface of the substrate with a dipole moment that is perpendicular to the surface of the substrate in order to dictate a crystal structure of the solid-state layer.

In accordance with an added feature of the invention, the step of introducing the auxiliary substance includes feeding the auxiliary substance into the reaction space from an external supply source.

In accordance with an additional feature of the invention, the external supply source is a storage container.

In accordance with another feature of the invention, the method includes steps of: pumping reaction products away from the reaction space during the chemical vapor deposition; and providing the auxiliary substance to essentially include the reaction products.

In accordance with a further feature of the invention, the solid-state layer is a layer selected from the group consisting of a ferroelectric layer and a paraelectric layer.

In accordance with a further added feature of the invention, the solid-state layer has a Perowskite structure.

In accordance with a further additional feature of the invention, the method includes steps of: providing the reaction space as an interior space of a reactor chamber; providing a distributor plate in the interior space of the reactor chamber; providing the reactor chamber with a reactor wall having a first side that is formed with inlet openings communicating with the interior space; performing the step of introducing the starting gasses and the auxiliary substance by introducing the starting gasses and the auxiliary substance through the inlet openings; providing the reactor wall with second side at which the substrate is mounted; providing the reactor chamber with a gas outlet; and pumping away reaction products through the gas outlet.

In accordance with yet an added feature of the invention, the distributor plate is a perforated plate.

In accordance with yet an additional feature of the invention, a carrier gas is introduced through the inlet openings.

In accordance with yet a further feature of the invention, the method includes steps of providing the reactor chamber with a further gas outlet opening formed in the reactor wall downstream of the substrate; and providing a connecting line connecting the gas outlet opening to one of the inlet openings that is located downstream of the distributor plate.

In accordance with an added additional feature of the invention, a valve for controlling gas flow is configured in the connecting line.

One of the main ideas for producing a crystalline, ferroelectric or paraelectric solid-state layer on a substrate by chemical vapor deposition (CVD), is to introduce into the reaction space, in addition to the starting gases containing the elements of the solid-state layer to be deposited, at least one auxiliary substance which is of such a form that it contains molecules which have a dipole moment and additionally have the property of briefly attaching themselves during the deposition process to the substrate surface with a dipole moment perpendicular to the substrate surface, in order in this way to dictate the crystal structure of the layer to be grown on.

The method is based on the realization gained from simulation calculations and experiments that, in the deposition process, as it was carried out in the past, polar molecules of this type play an important part in making the layer grow on with the correct prior alignment of the subsequent ferroelectric layer. It was found that polar molecules such as water or methanol as decomposition products of the precursors occur in the various reactions, and as an adsorbate, align themselves with their dipole moment perpendicular to the surface and consequently influence the prior alignment of the subsequent ferroelectric layer, and consequently its polarizability.

The molecules released by the surface reaction of the precursors on free surface locations, in particular radicals, initially undergo further reactions, to be precise alternatively both in the vapor phase and on the outerlying reactor walls. The molecules with a dipole moment occurring in this secondary reaction, in particular radicals, then diffuse back against the gas flow, on account of differences in concentration, to the wafer and occupy reactive surface locations. Since these polar molecules influence the layer growth in the way described above, but are not present with a constant density above the wafer, inhomogeneities occur in the growth process. It was therefore initially attempted to suppress the influence of these polar molecules in the process evaluation for the deposition of SBT layers. This was achieved by reducing the distance between the distributor plate and the wafer. In this case, the reaction products are pumped away essentially completely and there is no appreciable diffusion back and attachment to the surface. However, it was found that, although the layer then grows on in a spatially homogeneous manner and with a constant layer thickness, it has no ferroelectric properties. The polar molecules are thus obviously necessary for the production of a layer with ferroelectric properties.

The present invention draws from this the consequence of selectively admixing molecules with a dipole moment in a low concentration to the gas mixture used, including metal-organic precursors and carrier gas, in the reaction space, by which the desired alignment of the layer to be grown on can be favorably influenced. In particular when depositing the materials stated at the beginning, which crystallize in the Perowskite structure, according to the invention the desired alignment in the Perowskite structure can be achieved. In this way, the polar molecules are brought in a controlled manner to the substrate surface from all sides and not—as before—only by diffusion from the outer regions of the reactor. The quantity of the auxiliary substance fed in provides a further possible way of controlling the process beyond the existing variables such as the composition in the vapor phase, temperature and pressure.

However, the invention can be applied not only to ferroelectric layers with a Perowskite structure, but in general to all solid-state layers which require a certain alignment and/or layer sequence of the crystal structure. The polar molecules absorbed in the meantime act, as it were, as a virtual framework which constantly changes its form, since the polar molecules are in each case only briefly absorbed, to provide the correct alignment of the layer to be grown on in their immediate vicinity, and subsequently diffuse back into the vapor phase.

In a first way of implementing the invention, the type of auxiliary substance is decided in advance and the auxiliary substance is fed to the reaction space, preferably via a dedicated feed opening, from an external supply source, such as a storage container or the like. The auxiliary substance may be, for example, water or methanol; in both cases, the corresponding water or methanol molecules have a dipole moment.

In most reactions involving metal-organic precursors, water also occurs as a decomposition product of the secondary reactions mentioned further above. Therefore, according to a second way of implementing the invention, the reaction products of the deposition process of the reaction chamber pumped away from the reaction chamber can also be fed once again to some other location. In this case, the auxiliary substance is consequently formed essentially by the reaction products pumped away from the reaction chamber. This second type of implementation can be used generally in all cases in which it is known that reaction products whose molecules have a dipole moment exist.

The method is preferably carried out in a reactor chamber in which there is arranged a distributor plate, in particular a perforated plate, on one side of which the starting gases for the deposition process, the auxiliary substance and, if appropriate, a carrier gas are introduced through inlet openings in the reactor wall, and on the other side of which the substrate is mounted. In a reactor wall lying opposite the inlet openings of the reactor chamber there is an outlet opening, which is connected to a pump with which the reaction products are pumped away from the reactor chamber.

For the first way of implementing the invention, the inlet opening for the auxiliary substance is connected to an external storage container, whereas for the second way of implementing the invention this inlet opening is connected to an outlet opening which is located downstream of the substrate in a reactor wall and through which the reaction products are passed, and consequently fed back once again into the reactor chamber on one side of the distributor plate.

In the case of the reactor concept used, the conditions of chemical vapor deposition depend to a great extent on the distance of the distributor plate from the substrate. When there is a relatively great distance, a situation such as that described at the beginning occurs, that is in which a certain density of reaction products occurs over the substrate wafer by back diffusion or the like. In this case, the density of the fed-in auxiliary substance and the density of these reaction products are superposed, which may lead to inhomogeneities during growth. In a preferred way of implementing the invention, the chemical vapor deposition is therefore carried out in such a way that no appreciable back diffusion of the reaction products occurs, with the result that molecules by which the growth of the layer is positively influenced are supplied essentially or entirely by the fed-in auxiliary substance. This ensures that the density of molecules of this type over the substrate is spatially constant. This can be achieved by setting a relatively small distance between the distributor plate and the substrate wafer. The distance should be less than 2 cm, preferably approximately 1 cm.

Other features which are considered as characteristic for the invention are set forth in the appended claims.

Although the invention is illustrated and described herein as embodied in Method of producing a ferroelectric solid-state layer using an auxiliary substance, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 shows a cross-sectional view of a first embodiment of a reactor chamber;

FIG. 2 shows a cross-sectional view of a second embodiment of a reactor chamber.

### DESCRIPTION OF THE PREFERRED EMBODIMENTS

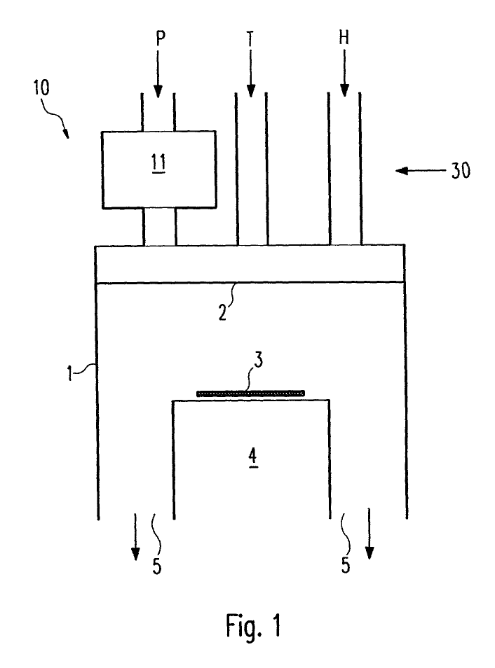

Referring now to the figures of the drawing in detail and first, particularly, to FIG. 1 thereof, there is shown a reactor chamber 10 that is designed, for example, in a cylindrical form. The reactor chamber 10 has a reactor wall 1, which has an upper end face with three inlet openings 30 through which starting gases such as suitable precursors P, a carrier gas T and an auxiliary substance H are fed to the reactor chamber 10. The precursor P is generally fed in, in liquid form and is transformed in an evaporator 11 into the gaseous state. At a distance below the inlet openings there is a distributor plate 2, generally a perforated plate, by which an approximately laterally homogeneous gas flow is produced. At a distance from the distributor plate 2, a substrate wafer 3 is mounted in a suitable way on a heatable susceptor 4. In the lower end face of the reactor vessel, lying opposite the inlet openings, there is a gas outlet 5, connected to which is a pump by which the reaction products are pumped away.

For the case of depositing BST, the precursors P Ti (ipro)₂ (thd)₂ (ipro=isopropoxy), thd=2,2,6,6-tetramethylheptane-3,5-diketone, Ba (thd)₂ and Sr (thd)₂ are used, for example. In the case of depositing SBT, the precursors P Sr (thd)₂, Bi (thd)₃ and Ta (ipro)₄ (thd) are used, for example. Argon and oxygen may be used for example as the carrier gas T. Water or methanol from an external supply container may be fed in as the auxiliary substance H.

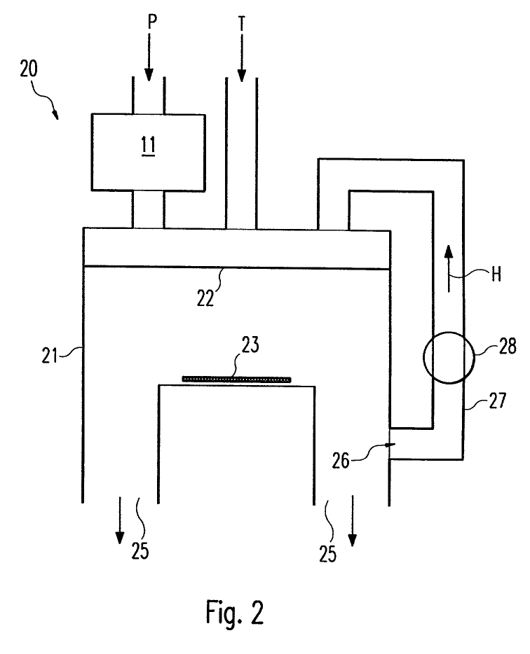

FIG. 2 shows an embodiment of a reactor chamber 20 that has, in addition to the gas outlet 25, a further lateral opening 26 in the reactor wall 21 downstream of the substrate 23. This additional outlet opening 26 is connected by a pipeline 27 to the inlet opening intended for the inlet of the auxiliary substance H into the reactor chamber 20. The auxiliary substance H is in this case formed by part of the pumped-away reaction products. The gas flow of the reaction products returned in the pipeline 27 can be controlled by a valve 28.

The case in which the two types of implementation are combined with each other, with both an auxiliary substance H being fed in from outside and the reaction products being returned into the reactor chamber, is also conceivable.

With the method according to the invention, a ferroelectric storage capacitor and a DRAM semiconductor memory containing the storage capacitor can be produced. In this case, the surface of the substrate 3 (FIG. 1) or 23 (FIG. 2) is formed by the lower electrode layer of the storage capacitor.

With the method, a ferroelectric memory transistor can likewise be produced, in which case the surface of the substrate 3 (FIG. 1) or 23 (FIG. 2) is formed by the channel portion of an MOS transistor.

We claim:

1. A method of producing a crystalline solid-state layer by chemical vapor deposition, which comprises:
providing a substrate having a surface in a reaction space;
performing chemical vapor deposition by introducing, into the reaction space, starting gases containing elements of a solid-state layer to be deposited on the surface of the substrate and introducing, into the reaction space, at least one auxiliary substance; and
providing the auxiliary substance in a form containing molecules which have a dipole moment and which have a property of briefly attaching themselves, during a deposition process, to the surface of the substrate with a dipole moment that is perpendicular to the surface of the substrate in order to dictate a crystal structure of the solid-state layer.

2. The method according to claim 1, wherein the step of introducing the auxiliary substance includes feeding the auxiliary substance into the reaction space from an external supply source.

3. The method according to claim 2, which comprises providing the external supply source as a storage container.

4. The method according to claim 1, which comprises:
pumping reaction products away from the reaction space during the chemical vapor deposition; and
providing the auxiliary substance to essentially include the reaction products.

5. The method according to claim 1, which comprises providing the solid-state layer as a layer selected from the group consisting of a ferroelectric layer and a paraelectric layer.

6. The method according to claim 5, which comprises providing the solid-state layer with a Perowskite structure.

7. The method according to claim 1, which comprises:
providing the reaction space as an interior space of a reactor chamber;
providing a distributor plate in the interior space of the reactor chamber;
providing the reactor chamber with a reactor wall having a first side that is formed with inlet openings communicating with the interior space;
performing the step of introducing the starting gasses and the auxiliary substance by introducing the starting gasses and the auxiliary substance through the inlet openings;
providing the reactor wall with second side at which the substrate is mounted;
providing the reactor chamber with a gas outlet; and
pumping away reaction products through the gas outlet.

8. The method according to claim 7, which comprises providing the distributor plate as a perforated plate.

9. The method according to claim 7, which comprises introducing a carrier gas through the inlet openings.

10. The method according to claim 7, which comprises:
providing the reactor chamber with a further gas outlet opening formed in the reactor wall downstream of the substrate; and
providing a connecting line connecting the gas outlet opening to one of the inlet openings that is located downstream of the distributor plate.

11. The method according to claim 10, which comprises configuring, in the connecting line, a valve for controlling gas flow.
